(19) United States
(12) Patent Application Publication
(10) Pub. No.: US 2019/0201949 A1
(43) Pub. Date: Jul. 4, 2019

(54) SUBSTRATE PROCESSING DEVICE

(71) Applicant: SCREEN HOLDINGS CO., LTD., Kyoto-shi, Kyoto (JP)

(72) Inventors: Nobuaki OKITA, Kyoto-shi, Kyoto (JP); Joichi NISHIMURA, Kyoto-shi, Kyoto (JP)

(73) Assignee: SCREEN Holdings Co., Ltd., Kyoto-shi, Kyoto (JP)

(21) Appl. No.: 16/312,341

(22) PCT Filed: Sep. 4, 2017
(86) PCT No.: PCT/JP2017/031750

§ 371 Date: Dec. 21, 2018

(30) Foreign Application Priority Data
Sep. 13, 2016 (JP) 2016-178383
Aug. 21, 2017 (JP) 2017-158408

(51) Int. Cl. B08B 15/02; H01L 21/67; B08B 3/02; B01D 46/00

(52) U.S. Cl. CPC B08B 15/02; H01L 21/67051; B01D 2279/35; B01D 46/0041; B01D 46/0017; B08B 3/022

(57) ABSTRACT

A substrate processing device includes: a chamber; a substrate processing mechanism that has a holding member, and discharges a processing fluid onto a substrate held by the holding member; a joint pipe that has a lower opening provided below the holding member, and an upper opening provided above the holding member, and is disposed such that at least part of the joint pipe from the lower opening to the upper opening passes through the outside of the chamber; and an air flow generator that is provided in the joint pipe. The air flow generator circulates an atmosphere in the chamber by discharging the atmosphere in the chamber from the lower opening to the joint pipe to allow the atmosphere to pass through the joint pipe, thereby introducing the atmosphere again into the chamber via the upper opening so that a downflow of the atmosphere occurs in the chamber.

### TECHNICAL FIELD

The present invention relates to a substrate processing device that processes a semiconductor wafer, a glass substrate for a liquid crystal display apparatus, a glass substrate for a plasma display, a substrate for an optical disk, a substrate for a magnetic disk, a substrate for a magneto-optical disk, a glass substrate for a photomask, a substrate for a solar cell, or the like (hereinafter simply referred to as a “substrate”).

### BACKGROUND ART

As such a substrate processing device, for example, a substrate processing device 500 illustrated in FIG. 3 is adopted. This device includes four chambers (housings) 1210 stacked in a top-bottom direction. In each chamber 1210, a holding member (not illustrated) for holding a substrate (not illustrated) in a horizontal state, and a cup 310 surrounding the holding member are provided. This device processes a substrate by discharging a processing liquid from, for example, a nozzle (not illustrated) onto the substrate held by the holding member. The device includes an introduction pipe 670 connected to an atmospheric air supply source (not illustrated) such as a clean room.

A fan 820 is provided in the introduction pipe 670, and when the fan 820 is operated, atmospheric air is introduced from the atmospheric air supply source to the introduction pipe 670. The introduction pipe 670 includes four branch pipes 680 corresponding to the respective chambers 1210. Each branch pipe 680 is disposed so as to extend to the inside of the corresponding chamber 1210. An ultra low penetration air (ULPA) filter 710 disposed above each cup 310 is mounted to the front end of each branch pipe 680. The atmospheric air introduced into the introduction pipe is cleaned by the filter 710, becomes a downflow D100, and flows toward the cup 310. In the cup 310, an atmosphere including mists of the processing liquid discharged onto the substrate is formed.

A collection tank 620 for recovering the discharged atmosphere is provided below the four chambers. Each branch pipe 610 of a discharge pipe 600 for discharging the atmosphere in the cup 310 is extended from the collection tank 620 to a lower side of the cup 310 of each chamber 1210. The branch pipe 610 of the discharge pipe 600 has an opening on the lower side of the cup 310. The atmosphere in the cup 310 is introduced from the opening into the branch pipe 610 of the discharge pipe 600, passes through the branch pipe 610, and reaches the collection tank 620. A pipe 530 for exhaust equipment that causes exhaust equipment 910 of a factory to communicate with the collection tank 620 is connected to the collection tank 620. The atmosphere collected in the collection tank 620 passes through the pipe 530 for the exhaust equipment and is discharged by the exhaust equipment 910 of the factory.

Normally, a plurality of processing devices is connected to the exhaust equipment 910 of the factory, and the exhaust amount of the exhaust equipment 910 is allocated among the plurality of processing devices. In a case where the exhaust amount of the exhaust equipment 910 allocated to the above substrate processing device 500 is insufficient compared with the required exhaust amount of the substrate processing device 500, the substrate processing device 500 cannot sufficiently discharge the atmosphere in the cup 310. Therefore, if substrate processing is performed, quality of processing will be degraded. As the countermeasure therefore, Patent Document 1 discloses a substrate processing device intended to suppress shortage of the exhaust amount of exhaust equipment allocated to the substrate processing device.

The substrate processing device according to Patent Document 1 includes a substrate holding part that holds a substrate in a horizontal state and is rotatable, a cup that surrounds the periphery of the substrate holding part, an exhaust pipe path that guides an atmosphere inside the cup to exhaust equipment of a factory, and an exhaust assist device provided in the middle of the exhaust pipe path. The exhaust assist device includes a branch pipe path that branches off from the exhaust pipe path, and a confluent pipe path that is joined to the exhaust pipe path on the downstream side of the flow of the atmosphere flowing through the exhaust pipe path. Between the branch pipe path and the confluent pipe path, a storage part for causing the branch pipe path to communicate with the confluent pipe path is provided. On a branch pipe path side of the storage part, an intake device such as a fan is provided. When the intake device operates, part of the atmosphere flowing through the exhaust pipe path is introduced into the branch pipe path and is sent to the storage part. The storage part is configured of a membrane member, and when the atmosphere is sent, the storage part inflates and stores the atmosphere. When the intake device stops, the storage part contracts and discharges the stored atmosphere to the confluent pipe. As a result, discharge capacity of the substrate processing device can be increased without extending the exhaust equipment of the factory.

### PRIOR ART DOCUMENTS

### Patent Documents

Patent Document 1: Japanese Patent Application Laid-Open No. 10-137662 (1998)

### SUMMARY

### Problem to be Solved by the Invention

However, in the substrate processing device according to Patent Document 1, there is a limit in the size to which the storage part can be inflated. Therefore, there is a problem that in a case where the shortage amount of the exhaust amount allocated by the exhaust equipment compared with the required exhaust amount of the substrate processing device exceeds the maximum storage amount of the storage part, the atmosphere cannot be sufficiently discharged.

The present invention has been made in order to solve such a problem, and an objective of the present invention to provide a technique of sufficiently discharging an atmosphere in a chamber even in a case where the exhaust amount allocated by external exhaust equipment to a substrate processing device is quite insufficient compared with the required exhaust amount of the substrate processing device.

### Means to Solve the Problem

In order to solve the above problem, a substrate processing device according to a first aspect includes: a chamber; a substrate processing mechanism that has a holding member capable of holding a substrate in a substantially horizontal state, is housed in the chamber, and discharges a processing fluid onto a substrate held by the holding member to process the substrate; a joint pipe that has a lower opening provided below the holding member and facing the inside of the chamber, and an upper opening provided above the holding member and facing the inside of the chamber, and is disposed such that at least part of the joint pipe from the lower opening to the upper opening passes through the outside of the chamber; and an air flow generator that is provided in the joint pipe. The air flow generator circulates an atmosphere containing a specific gas in the chamber by discharging the atmosphere in the chamber from the lower opening to the joint pipe to allow the atmosphere to pass through the joint pipe, thereby introducing the atmosphere again into the chamber via the upper opening so that a downflow of the atmosphere occurs in the chamber.

A substrate processing device according to a second aspect is the substrate processing device according to the first aspect further including a filter that is provided in the joint pipe and is capable of removing a specific component included in the processing fluid from the atmosphere discharged from the chamber into the joint pipe.

A substrate processing device according to a third aspect is the substrate processing device according to the second aspect, in which the filter is provided on an upstream side of a flow of the atmosphere circulated by the air flow generator with respect to the air flow generator.

A substrate processing device according to a fourth aspect is the substrate processing device according to the third aspect, in which the processing fluid contains a specific liquid, the joint pipe includes a vertical pipe extending in a top-bottom direction, the vertical pipe is disposed such that the flow of the atmosphere circulated by the air flow generator is capable of rising inside the vertical pipe and at least part of the vertical pipe is located on the upstream side of the flow of the atmosphere with respect to the air flow generator, and the filter is provided in the at least part of the vertical pipe and is capable of removing the liquid in a form of mist from the atmosphere.

A substrate processing device according to a fifth aspect is the substrate processing device according to the fourth aspect, in which the joint pipe includes a tank provided at a lower end in a vertical direction, the tank is provided so as to be capable of receiving the liquid mixed with the atmosphere and discharged from the chamber to the joint pipe, and the vertical pipe extends upward from the tank such that an internal space of the vertical pipe and an internal space of the tank communicate with each other.

A substrate processing device according to a sixth aspect is the substrate processing device according to the fifth aspect, in which the filter is provided in a section of the vertical pipe, closer to the tank than to the air flow generator.

A substrate processing device according to a seventh aspect is the substrate processing device according to any one of the first to sixth aspects further including: an introduction pipe that causes a supply source of the specific gas and the joint pipe to communicate with each other so as to be capable of introducing the gas into the joint pipe; and a regulating valve that is capable of regulating a flow rate of the gas flowing through the introduction pipe.

A substrate processing device according to an eighth aspect is the substrate processing device according to the seventh aspect further including a filter that is provided in the joint pipe and is capable of removing a specific component contained in the processing fluid from the atmosphere discharged from the chamber into the joint pipe, in which the filter is provided on the upstream side of the flow of the atmosphere circulated by the air flow generator with respect to the air flow generator, and the introduction pipe is connected to a section of the joint pipe, on a downstream side of the flow of the atmosphere with respect to the filter.

A substrate processing device according to a ninth aspect is the substrate processing device according to the first aspect further including a pipe for exhaust equipment that branches off from the joint pipe to cause the joint pipe to communicate with external exhaust equipment, and guides the atmosphere discharged to the joint pipe to the exhaust equipment, and further including an on-off valve mechanism that is capable of bringing one of a return pipe and the pipe for exhaust equipment into an open state and bringing the other into a closed state when the return pipe is defined by a section of the joint pipe ranging from a downstream side of a flow of the atmosphere circulated by the air flow generator with respect to the pipe for exhaust equipment to the upper opening.

A substrate processing device according to a tenth aspect is the substrate processing device according to the ninth aspect further including a controller that performs opening and closing control of the on-off valve mechanism so that one of the return pipe and the pipe for exhaust equipment is in the open state and the other is in the closed state, in which the opening and closing control is control for bringing the return pipe into the open state and the pipe for exhaust equipment into the closed state when a required exhaust amount of the substrate processing device exceeds an exhaust amount allocated to the substrate processing device out of an exhaust amount of the exhaust equipment and for bringing the return pipe into the closed state and the pipe for exhaust equipment into the open state when the required exhaust amount does not exceed the exhaust amount allocated.

A substrate processing device according to an eleventh aspect is the substrate processing device according to the tenth aspect, in which the controller performs the opening and closing control according to control information acquired in advance, and the control information includes information in which a process of substrate processing that the substrate processing device is capable of executing and an opening and closing state of the on-off valve mechanism are correlated with each other so that the opening and closing control can be performed.

A substrate processing device according to a twelfth aspect is the substrate processing device according to the tenth aspect, in which the controller performs the opening and closing control according to control information acquired in advance, and the control information includes an index value corresponding to an exhaust amount allocated to the substrate processing device by the exhaust equipment and an index value corresponding to the required exhaust amount of the substrate processing device.

A substrate processing device according to a thirteenth aspect is the substrate processing device according to any one of the ninth to twelfth aspects, in which the processing fluid contains a specific liquid, the joint pipe includes a tank provided at a lower end of the joint pipe in a vertical direction, the tank is provided so as to be capable of receiving the liquid mixed with the atmosphere and discharged from the chamber into the joint pipe, the pipe for exhaust equipment and the return pipe are connected to the tank, the return pipe includes a vertical pipe extending upward from the tank, and the vertical pipe is provided so that a flow of the atmosphere circulated by the air flow generator is capable of rising inside the vertical pipe and at least part of the vertical pipe is located on an upstream side of the flow of the atmosphere with respect to the air flow generator, the substrate processing device further including a filter that is provided in the at least part of the vertical pipe and is capable of removing the liquid in a form of mist from the atmosphere, in which the on-off valve mechanism includes a first on-off valve that is provided at a section of the vertical pipe, on an upstream side of the flow of the atmosphere circulated by the air flow generator with respect to the filter and is capable of opening and closing the vertical pipe, and a second on-off valve capable of opening and closing the pipe for exhaust equipment.

A substrate processing device according to a fourteenth aspect is the substrate processing device according the thirteenth aspect further including: an introduction pipe that causes a supply source of the specific gas and the vertical pipe to communicate with each other so as to be capable of introducing the gas into the vertical pipe; and a regulating valve that is capable of regulating a flow rate of the specific gas flowing through the introduction pipe, in which the introduction pipe is connected to a section of the joint pipe, on a downstream side of the flow of the atmosphere circulated by the air flow generator with respect to the filter.

A substrate processing device according to a fifteenth aspect is the substrate processing device according to the first aspect, in which the substrate processing mechanism discharges the processing fluid onto the substrate to perform one of cleaning processing and rinsing processing of the substrate.

A substrate processing device according to a sixteenth aspect is the substrate processing device according to the fifteenth aspect, in which the substrate processing mechanism discharges one of pure water and functional water as the processing fluid.

### Effects of the Invention

According to the invention according to the first aspect, the joint pipe includes the lower opening and the upper opening each of which faces the inside of the chamber, and is disposed such that at least part thereof from the lower opening to the upper opening passes through the outside of the chamber. The air flow generator provided in the joint pipe circulates the atmosphere containing the specific gas in the chamber by discharging the atmosphere in the chamber from the lower opening to the joint pipe to allow the atmosphere to pass through the joint pipe, thereby introducing the atmosphere again into the chamber via the upper opening so that a downflow of the atmosphere occurs in the chamber. Thus, the substrate processing device can discharge the atmosphere in the chamber to the outside of the chamber even if the substrate processing device is not connected to the external exhaust equipment. Therefore, the substrate processing device can sufficiently discharge the atmosphere in the chamber even in a case where the exhaust amount allocated by the external exhaust equipment is quite insufficient compared with the required exhaust amount.

According to the invention according to the second aspect, the substrate processing device further includes the filter provided in the joint pipe and capable of removing the specific component contained in the processing fluid from the atmosphere discharged from the chamber into the joint pipe. Therefore, the atmosphere discharged from the chamber to the joint pipe is purified by the filter and is then circulated into the chamber again. As a result, the quality of substrate processing can be improved.

According to the invention according to the third aspect, the filter is provided on the upstream side of the flow of the atmosphere circulated by the air flow generator with respect to the air flow generator. Therefore, since the atmosphere purified by the filter is sent to the air flow generator, deterioration of the air flow generator due to the component of the processing fluid mixed in the atmosphere can be suppressed.

According to the invention according to the fourth aspect, the processing fluid contains the specific liquid, and the filter is capable of removing the liquid in the form of mist from the atmosphere and is provided in a section of the vertical pipe included in the joint pipe, on the upstream side of the flow of the atmosphere with respect to the air flow generator. Therefore, the liquid in the form of mist in the atmosphere separated by the filter easily drips downward along the vertical pipe.

According to the invention according to the fifth aspect, since the tank is provided at the lower end in the vertical direction of the joint pipe, drops (large droplets) of the specific liquid discharged to the joint pipe together with the atmosphere in the chamber flow into the tank along an inner wall of the joint pipe and are received by the tank. The liquid in the form of mist mixed with the atmosphere and is discharged to the joint pipe flows from the tank to the vertical pipe together with the atmosphere, but the liquid is removed by the filter. Therefore, on the downstream side of the flow of the atmosphere with respect to the filter, the atmosphere from which both the liquid in the form of drops and the liquid in the form of mist are removed flows. Therefore, deterioration of the air flow generator due to the component of the processing fluid is efficiently suppressed.

According to the invention according to the sixth aspect, the filter is provided in a section of the vertical pipe, closer to the tank than to the air flow generator. When the liquid in the form of mist in the processing fluid is separated from the atmosphere by the filter and becomes drops, and the drops drip down along the inner peripheral surface of the vertical pipe, if many drops adhere to the inner peripheral surface, resistance that the atmosphere flowing through the vertical pipe receives increases. However, if the filter is closer to the tank than to the air flow generator in the vertical pipe, the range where drops adhere can be made smaller, so that the flow of the atmosphere in the vertical pipe becomes smooth.

According to the invention according to the seventh aspect, the substrate processing device further includes: the introduction pipe that causes the supply source of the specific gas contained in the atmosphere in the chamber and the joint pipe to communicate with each other so as to be capable of introducing the gas into the joint pipe; and the regulating valve that is capable of regulating the flow rate of the gas flowing through the introduction pipe. Therefore, even in a case where the gas leaks from the chamber to the outside, the gas can be filled in the chamber via the joint pipe, the introduction pipe, and the regulating valve.

According to the invention according to the eighth aspect, the filter is provided on the upstream side of the flow of the atmosphere circulated by the air flow generator with respect the air flow generator, and the introduction pipe is connected to the section of the joint pipe on the downstream side of the flow of the atmosphere with respect to the filter. Therefore, it is possible to suppress mixing of the specific component of the processing fluid into the specific gas introduced into the joint pipe from the introduction pipe, the processing fluid being mixed with the atmosphere and discharged to the joint pipe from the chamber, and to suppress deterioration of the air flow generator due to the component of the processing fluid.

According the invention according to the ninth aspect, the substrate processing device further includes the on-off valve mechanism that brings one of the return pipe and the pipe for exhaust equipment into the open state and brings the other into the closed state. Therefore, the substrate processing device can selectively perform circulation of the atmosphere in the chamber discharged from the chamber into the chamber via the return pipe and discharge of the atmosphere into the exhaust equipment via the pipe for exhaust equipment.

According to the invention according to the tenth aspect, the controller performs control for circulating the atmosphere discharged from the chamber into the chamber via the return pipe when the required exhaust amount of the substrate processing device exceeds the exhaust amount allocated to the substrate processing device out of the exhaust amount of the exhaust equipment, and performs control for discharging the atmosphere into the exhaust equipment via the pipe for exhaust equipment when the required exhaust amount does not exceed the allocated exhaust amount. Therefore, the substrate processing device can circulate the atmosphere only in a case where the exhaust amount allocated to the device from the exhaust equipment is insufficient.

According to the invention according to the eleventh aspect, the control information includes information in which the process of substrate processing that the substrate processing device is capable of executing and the opening and closing state of the on-off valve mechanism are correlated with each other so that the opening and closing control can be executed. Therefore, the controller can perform control for circulating the atmosphere in the case of performing the process of the substrate processing in which the exhaust amount allocated to the device by the exhaust equipment is insufficient, and can perform control for discharging the atmosphere to the exhaust equipment in the case of executing the process of the substrate processing in which the exhaust amount is not insufficient.

According to the invention according to the twelfth aspect, the control information includes the index value corresponding to the exhaust amount allocated to the substrate processing device by the exhaust equipment and the index value corresponding to the required exhaust amount of the substrate processing device. Therefore, the controller can make a determination as to whether or not the exhaust amount allocated to the substrate processing device by the exhaust equipment is insufficient compared with the required exhaust amount of the substrate processing device, and can perform the opening and closing control of the on-off valve mechanism according to the determination.

According to the invention according to the thirteenth aspect, the on-off valve mechanism includes the first on-off valve that is provided at the section of the vertical pipe on the upstream side of the flow of the atmosphere circulated by the air flow generator with respect to the filter and is capable of opening and closing the vertical pipe, and the second on-off valve capable of opening and closing the pipe for exhaust equipment. Therefore, by opening one of the first on-off valve and the second on-off valve and closing the other, the substrate processing device can selectively perform circulation of the atmosphere in the chamber discharged from the chamber via the return pipe and discharge of the atmosphere to the exhaust equipment via the pipe for exhaust equipment.

According to the invention according to the fourteenth aspect, the substrate processing device further includes: the introduction pipe that causes the supply source of the specific gas and the vertical pipe to communicate with each other so as to be capable of introducing the gas into the vertical pipe; and the regulating valve that is capable of regulating the flow rate of the gas flowing through the introduction pipe, in which the introduction pipe is connected to the section of the joint pipe on the downstream side of the flow of the atmosphere circulated by the air flow generator with respect to the filter. Therefore, it is possible to suppress mixing of the specific component of the processing fluid into the specific gas introduced into the joint pipe from the introduction pipe, the processing fluid being mixed with the atmosphere and discharged to the joint pipe from the chamber, and to suppress deterioration of the air flow generator due to the component of the processing fluid.

According to the invention according to the sixteenth aspect, the substrate processing mechanism discharges as the processing fluid the pure water or the functional water to the substrate to perform the cleaning processing or the rinsing processing. Since the substrate processing mechanism does not use a chemical solution such as SC1, mists originating from the chemical solution are not generated. Therefore, when the atmosphere in the chamber is circulated by the joint pipe and is introduced into the chamber again, the likelihood that the substrate will be contaminated by the atmosphere can be reduced.

### BRIEF DESCRIPTION OF DRAWINGS

FIG. 1 is a side cross-sectional view schematically illustrating a substrate processing device according to Embodiment 1.

FIG. 2 is an enlarged view illustrating part of one substrate processing unit in FIG. 1.

FIG. 3 is a side cross-sectional view schematically illustrating a substrate processing device according to a comparative technique.

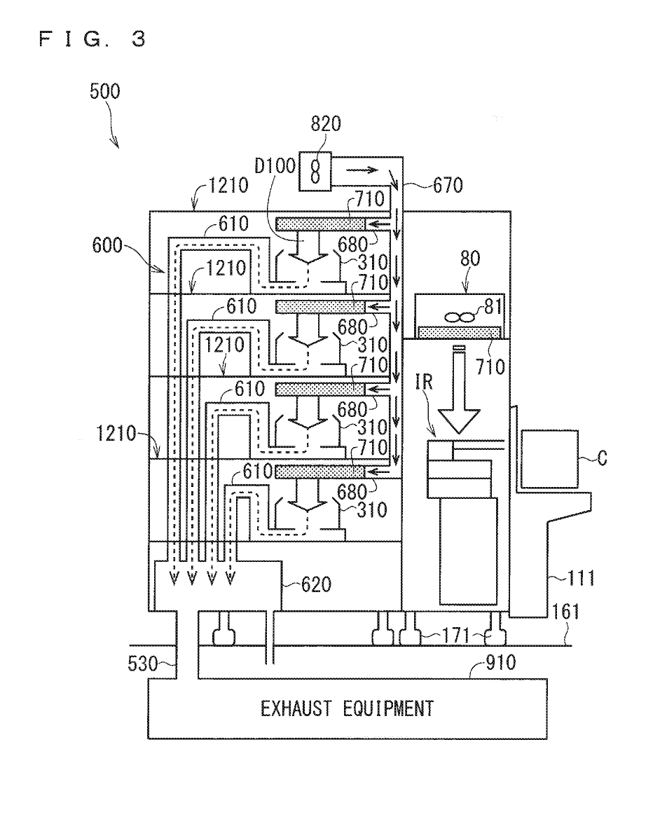

FIG. 4 is a side cross-sectional view schematically illustrating a substrate processing device according to Embodiment 2.

### DESCRIPTION OF EMBODIMENTS

Hereinafter, embodiments will be described with reference to the drawings. The following embodiments are examples embodying the present invention and are not cases of limiting the technical scope of the present invention. In addition, in each of the drawings referred to below, for easy understanding, the dimensions and the number of each part may be exaggerated or illustrated in a simplified manner. In addition, in each drawing, identical reference signs are given to parts having similar configurations and functions, and an overlapping explanation is omitted in the following description. The top-bottom direction is the vertical direction, and the top indicates a substrate side with respect to a spin chuck.

<1. Substrate Processing Device 100>

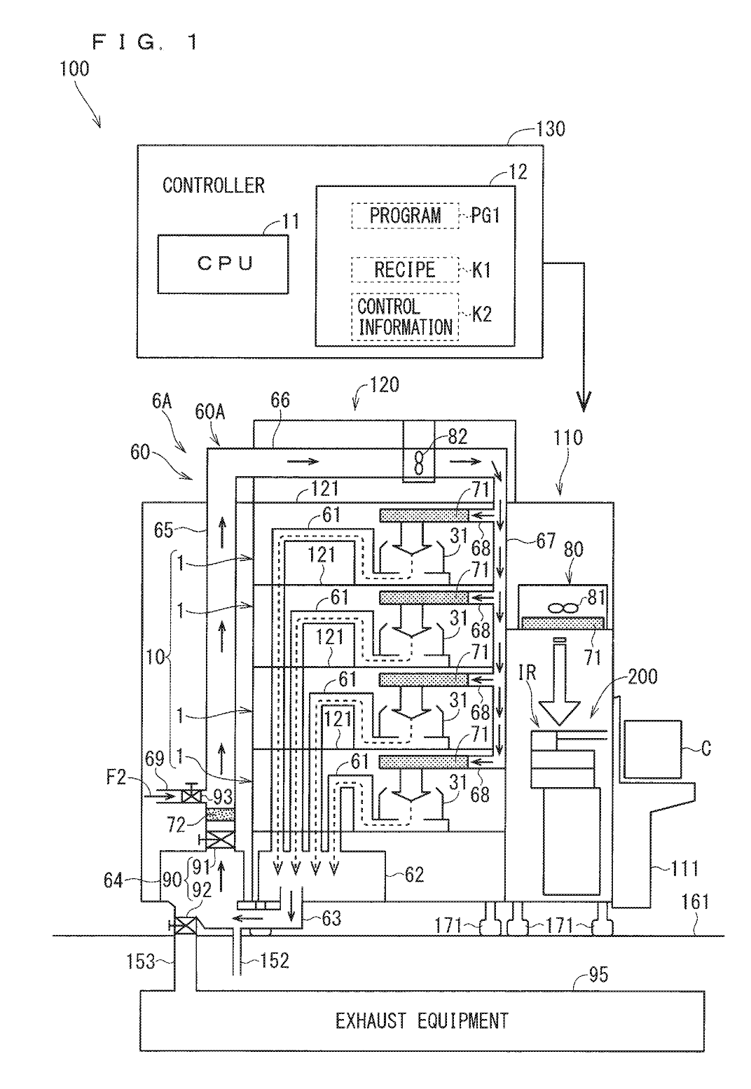

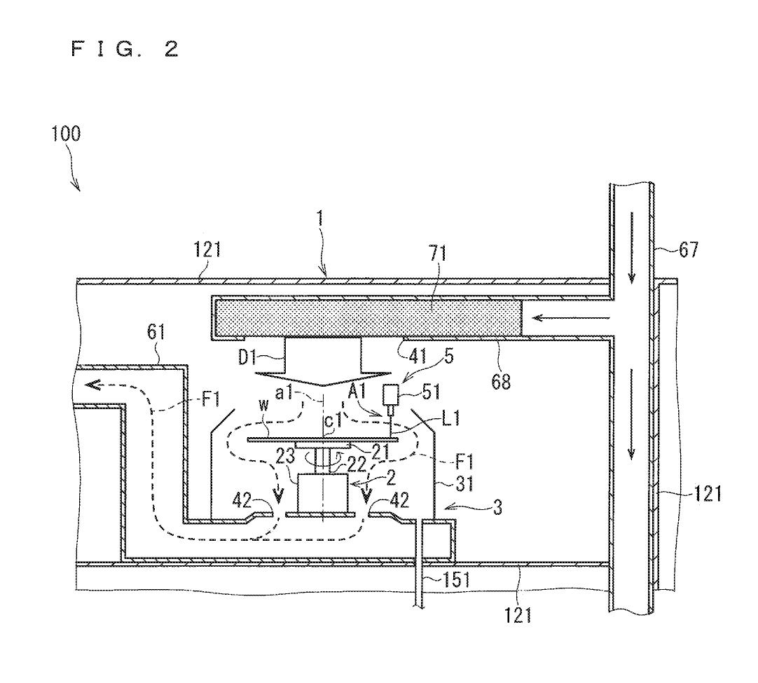

The configuration of a substrate processing device 100 will be described with reference to FIG. 1. FIG. 1 is a side cross-sectional view schematically illustrating the substrate processing device 100 according to Embodiment 1. FIG. 2 is an enlarged side cross-sectional view illustrating part of one substrate processing unit 1 of the substrate processing device 100.

The substrate processing device 100 is a system for processing a substrate W such as a semiconductor wafer. The front surface shape of the substrate W is substantially circular. The radius of the substrate W is, for example, 150 mm. The substrate processing device 100 includes a plurality of substrate processing units 1. The substrate processing device 100 can continuously process the substrates W one by one in the respective substrate processing units 1 and can also process simultaneously a plurality of substrates W in the plurality of substrate processing units 1.

The substrate processing device 100 includes a plurality of cells (processing blocks) (specifically, an indexer cell 110 and a processing cell 120) disposed in parallel to each other, and a controller 130 collectively controls respective operation mechanisms and the like included in the plurality of cells 110, 120. The controller 130 also controls a substrate carrying device 200 included in the plurality of cells 110, 120. The substrate processing device 100 is placed on a floor surface 161 of a factory or the like with a plurality of leg parts 171 interposed therebetween.

<Indexer Cell 110>

The indexer cell 110 is a cell for transferring an unprocessed substrate W received from outside the device to the processing cell 120 and for carrying the processed substrate W received from the processing cell 120 to the outside of the device. The indexer cell 110 includes a carrier stage 111 on which a carrier C is placed, and a transfer robot IR for carrying the substrate W into and out of the carrier C.

The carrier C housing therein a plurality of unprocessed substrates W is carried into and placed on the carrier stage 111 from outside the device by an overhead hoist transfer (OHT) or the like. The unprocessed substrates W are taken out one by one from the carrier C and processed in the device, and the processed substrates W which have been processed in the device are housed in the carrier C again. The carrier C housing therein the processed substrates W is carried to the outside of the device by the OHT or the like. In this manner, the carrier stage 111 functions as a substrate accumulating part that accumulates the unprocessed substrates W and the processed substrates W. Note that the mode of the carrier C may be a front opening unified pod (FOUP) housing therein the substrates W in a sealed space, a standard mechanical inter face (SMIF) pod, or an open cassette (OC) which exposes the housed substrates W to outside air.

The transfer robot IR can support the substrate W in a horizontal posture (a posture in which the main surface of the substrate W is horizontal). The transfer robot IR takes out an unprocessed substrate W from the carrier C placed on the carrier stage 111 and transfers the substrate W which has been taken out to a carrying robot (not illustrated) which will be described later. In addition, the transfer robot IR receives the processed substrate W from the carrying robot and causes the received substrate W to be housed in the carrier C placed on the carrier stage 111.

A fan-filter unit (FFU) 80 is provided above the transfer robot IR, and an exhaust device (not illustrated) for discharging a gas supplied from the FFU 80 is provided below the transfer robot IR. The FFU 80 includes a fan 81 and an ULPA filter 71. The FFU 80 sends clean air in the indexer cell 110. The FFU 80 and the exhaust device form a downflow (downward flow) in the indexer cell 110.

<Processing Cell 120>

The processing cell 120 is a cell for processing the substrate W. The processing cell 120 includes the plurality of substrate processing units 1, a circulation system 6A that discharges the atmosphere in a chamber 121 of each substrate processing unit 1 from the chamber 121 and circulates the atmosphere into the chamber 121 again, and a carrying robot that carries the substrate W into and out of the plurality of substrate processing units 1. The circulation system 6A will be described later.

The carrying robot and the transfer robot IR are the substrate carrying device 200. Here, a plurality of (for example, four) substrate processing units 1 is stacked in the vertical direction to constitute one substrate processing device group 10. In FIG. 1, the carrying robot is hidden behind the substrate processing device group 10 in the direction perpendicular to the paper surface. The plurality of (for example, four) substrate processing device groups 10 is disposed, for example, in a cluster shape (as a bunch) so as to surround the carrying robot. The substrate processing device 100 may include one substrate processing device group 10 or the substrate processing device group 10 may include one substrate processing unit 1.

Each substrate processing unit 1 includes the chamber (“housing”) 121 that forms a processing space therein. In the chamber 121, an inlet/outlet (not illustrated) through which a hand of the carrying robot is inserted into the chamber 121 is formed. A shutter (not illustrated) that can be opened and closed under control of the controller 130 is provided at the inlet/outlet. The shutter is opened when the substrate W is carried into or out of the chamber 121 and is closed during processing of the substrate W. The substrate processing unit 1 is disposed such that the inlet/outlet faces the space where the carrying robot is disposed. The specific configuration of the substrate processing unit 1 will be described later.

The carrying robot is a robot that carries the substrate W while supporting the substrate W in a cantilever manner. The carrying robot takes out the processed substrate W from the specified substrate processing unit 1 and transfers the substrate W which has been taken out to the transfer robot IR at a substrate transfer position. In addition, the carrying robot receives the unprocessed substrate W from the transfer robot IR at the substrate transfer position, and carries the received substrate W to the specified substrate processing unit 1.

<Controller 130>

The controller 130 controls operation of each of the group of substrate processing units 1. As the hardware configuration of the controller 130, for example, the hardware configuration similar to that of a general computer can be adopted. That is, for example, the controller 130 is configured by connecting, to a bus line (not illustrated) a CPU 11 that performs various arithmetic processes, a ROM (not illustrated) that is a read-only memory that stores a basic program, a RAM (not illustrated) that is a readable and writable memory which stores various pieces of information, and storage 12 that stores a program PG1, data and the like. A recipe K1 that defines the processing contents and the processing procedure of the substrate W are also stored in the storage 12. Control information K2 used for opening and closing control of an on-off valve mechanism 90 to be described later is also stored in the storage 12.

In the controller 130, the CPU 11 serving as a controller performs the arithmetic processing according to the procedure described in the program PG1, thereby realizing various functional units for controlling each part of the substrate processing device 100. Some or all of the functional units realized in the controller 130 may be realized as hardware by dedicated logic circuits or the like.

<2. Configuration of Substrate Processing Unit 1>

The configuration of the substrate processing unit 1 will be described below with reference to FIGS. 1 and 2.

FIG. 2 illustrates a state in which the substrate W is rotated in a specific rotation direction about a rotary axis a1 by a spin chuck (“holding member”) 21 in a state in which a nozzle 51 and a splash guard 31 are disposed at their respective processing positions. The carrying robot carries the substrate W into and out of the substrate processing unit 1 in a state in which the nozzle 51 and the splash guard 31 are disposed at retreat positions. The substrate W carried into the substrate processing unit 1 is detachably held by the spin chuck 21.

Note that in the following description, a “processing liquid” includes a “chemical solution” used for chemical-solution processing and a “rinse liquid (also referred to as a “cleaning liquid”) used for rinsing processing for rinsing out the chemical solution.

The substrate processing unit 1 includes a substrate processing mechanism A1 and a scattering prevention part 3. The substrate processing mechanism A1 is housed in the chamber 121. The inside of the chamber 121 is at atmospheric pressure. The substrate processing mechanism A1 is a mechanism that discharges a processing fluid to the substrate W held by the spin chuck 21 to process the substrate W. The substrate processing mechanism A1 includes a rotating and holding mechanism 2 and a processor 5. The rotating and holding mechanism 2, the scattering prevention part 3, and the processor 5 are electrically connected to the controller 130, and operate according to an instruction from the controller 130. The controller 130 controls each part of the substrate processing unit 1 by causing the CPU 11 serving as a controller to perform arithmetic processing according to the procedure described in the program PG1.

<Rotating and Holding Mechanism 2>

The rotating and holding mechanism 2 is a mechanism that is rotatable while holding the substrate W in a substantially horizontal posture in a state where one main surface of the substrate W faces upward. The rotating and holding mechanism 2 rotates the substrate W about the vertical rotary axis a1 passing through a center c1 of the main surface.

The rotating and holding mechanism 2 includes a spin chuck (“holding member”) 21, which is a disk-shaped member smaller than the substrate W. The spin chuck 21 is provided such that the upper surface thereof is substantially horizontal, and the center axis thereof matches the rotary axis a1. A cylindrical rotating shaft part 22 is connected to the lower surface of the spin chuck 21. The rotating shaft part 22 is disposed in such a posture that the axis line thereof extends along the vertical direction. The axis line of the rotating shaft part 22 matches the rotary axis a1. In addition, a rotary drive unit (for example, a motor) 23 is connected to the rotating shaft part 22. The rotary drive unit 23 drives the rotating shaft part 22 so that the rotating shaft part 22 rotates about the axis line thereof. Therefore, the spin chuck 21 can rotate about the rotary axis a1 together with the rotating shaft part 22. The rotary drive unit 23 and the rotating shaft part 22 are a rotation mechanism for rotating the spin chuck 21 about the rotary axis a1.

The spin chuck 21 is provided with a plurality of suction ports (not illustrated) for sucking the substrate W. Each suction port opens on the upper surface (“front surface”) of the spin chuck 21. A pressure reducing mechanism (not illustrated) communicates with each suction port. The pressure reducing mechanism can perform pressure-reducing operation for reducing the pressure inside the suction port. In addition, the pressure reducing mechanism can also perform pressure recovering operation for recovering the reduced pressure (atmospheric pressure) in the suction port.

When the pressure reducing mechanism reduces the pressure inside the suction port in a state where the substrate W is placed on the upper surface of the spin chuck 21 in a substantially horizontal posture, the spin chuck 21 sucks the substrate W from below and holds the substrate W in a substantially horizontal state. In addition, when the pressure reducing mechanism recovers the pressure in the suction port, the substrate W can be detached from the upper surface of the spin chuck 21.

In this configuration, when the rotary drive unit 23 rotates the rotating shaft part 22 in a state in which the spin chuck 21 sucks the substrate W and holds the substrate W in a substantially horizontal state, the spin chuck 21 is rotated about the axis line along the vertical direction. As a result, the substrate W held on the spin chuck 21 is rotated about the vertical rotary axis a1 passing through the center c1 on the plane of the substrate W.

<Scattering Prevention Part 3>

The scattering prevention part 3 receives a processing liquid or the like scattered from the substrate W rotated together with the spin chuck 21. The scattering prevention part 3 includes the splash guard 31 and a raising and lowering mechanism (not illustrated) for raising and lowering the splash guard 31.

The splash guard 31 is a tubular member whose upper end is opened and is provided so as to surround the spin chuck 21. When the substrate W is processed, the splash guard 31 is disposed such that the upper end thereof is in a processing position above the substrate W held by the spin chuck 21, receives the processing liquid discharged from the peripheral edge of the substrate W, collects the processing liquid in the bottom part thereof, and discharges the processing liquid to a drainage line of a factory through a drain pipe 151 communicating with the space in the bottom part. When the substrate W is carried into the spin chuck 21, the splash guard 31 is disposed at a retracted position where the upper end thereof is located below the spin chuck 21. The raising and lowering mechanism of the splash guard 31 is electrically connected to the controller 130 and operates under control of the controller 130. That is, the position of the splash guard 31 is controlled by the controller 130.

Note that an upper opening 41 of a joint pipe 60 to be described later, facing the inside of the chamber 121, is formed above the spin chuck 21, and a lower opening 42 of the joint pipe 60, facing the space surrounded by the splash guard 31 is formed below the spin chuck 21. By operation of an air flow generator 82 to be described later, the atmosphere in the chamber 121 (space surrounded by the splash guard 31) is discharged from the lower opening 42 to the joint pipe 60. The discharged atmosphere becomes a gas (atmosphere) with which a relatively clean gas F2 introduced into the joint pipe 60 from an introduction pipe 69 to be described later is mixed and is introduced again into the chamber 121 via the upper opening 41. The introduced atmosphere forms a downflow D1 in the chamber 121, flows toward the lower opening 42 along the front surface of the substrate W or the like, and is discharged again from the lower opening 42 to the joint pipe 60.

<Processor 5>

The processor 5 performs specific processing on the substrate W held on the spin chuck 21. Specifically, for example, the processor 5 supplies the processing liquid to the substrate W held on the spin chuck 21, and processes the substrate W.

The processor 5 includes the nozzle 51. The nozzle 51 is moved between the processing position and a retracted position by a nozzle moving mechanism, not illustrated. The front end part (lower end part) of the nozzle 51 projects downward and has a discharge port at the front end thereof.

To the nozzle 51, a processing liquid supply part (not illustrated) which is a piping system for supplying the processing liquid to the nozzle 51 is connected. The processing liquid is supplied from the processing liquid supply part to the nozzle 51, and the processing liquid is discharged from the discharge port at the front end of the nozzle 51. The processor 5 discharges a liquid flow of a processing liquid L1 from the nozzle 51 under control of the controller 130.

The processing liquid supply part supplies the processing liquid (“processing fluid”) L1 to the nozzle 51. For example, SC1, DHF, SC2, a rinse liquid, or the like is adopted as the processing liquid L1. As the rinse liquid, pure water, warm water, ozone water, magnetic water, reduced water (hydrogen water), various organic solvents (ion water, WA (isopropyl alcohol), functional water (CO2 water, or the like), or the like is adopted. The nozzle to which the processing liquid L1 is supplied from the processing liquid supply part discharges the liquid flow of the processing liquid L1 so that the liquid flow hits the rotating substrate W. The processing liquid supply part includes an on-off valve (not illustrated) provided correspondingly to the nozzle 51. The on-off valve is opened and closed under control of the controller 130 by a valve opening and closing mechanism (not illustrated) electrically connected to the controller 130. That is, a discharge manner of the processing liquid from the nozzle 51 (specifically, the type, discharge start timing, discharge end timing, discharge flow rate, and the like of the processing liquid to be discharged) is controlled by the controller 130.

Note that in lieu of the processing liquid supply part, a processing fluid supply part for supplying an etching gas or the like may be adopted. In this case, the etching gas is supplied from the nozzle 51 to the substrate W, and the substrate W is etched.

<3. Configuration of Circulation System 6A>

The circulation system 6A discharges the atmosphere in the chamber 121 of the substrate processing unit 1 (more specifically, in the splash guard 31) from the substrate processing unit 1 and introduces the atmosphere again into the chamber 121 to circulate the atmosphere in the chamber 121. The circulation system 6A includes the joint pipe 60 and the air flow generator 82 provided in the joint pipe 60. The air flow generator 82 is configured by including, for example, a fan and the like.

The joint pipe 60 includes a plurality of (four in the illustrated example) pipes 61, a tank 62, a pipe 63, a tank 64, and a return pipe 60A. Each pipe 61 extends from below each splash guard 31 in each chamber 121, passes through each chamber 121, and is disposed outside each chamber 121. A front end of each pipe 61 is connected to the upper part of the tank 62. A lower opening 42 is formed in a section of each pipe 61 below the splash guard 31 so as to face the space surrounded by the splash guard 31 in the internal space of the chamber 121. The lower opening 42 is formed, for example, in an annular shape surrounding the bottom part of the rotary drive unit 23. The atmosphere in the space surrounded by each splash guard 31, that is, the atmosphere in each chamber 121 is discharged from each lower opening 42 to each pipe 61, that is, the joint pipe 60. In the joint pipe 60, a flow F1 of the discharged atmosphere is formed. In addition, the pipe 63 causes the tank 62 and the tank 64 to communicate with each other. The tank 64 is provided so as to be able to receive the processing liquid (liquid) L1 mixed in the atmosphere and discharged from the chamber 121 to the joint pipe 60. A vertical pipe 65 extends upward from the tank 64 so that the internal space thereof and the internal space of the tank 64 communicate with each other.

The circulation system 6A further includes a pipe 153 for exhaust equipment. The pipe 153 for exhaust equipment branches off from the joint pipe 60 and causes the joint pipe 60 to communicate with external exhaust equipment 95 and guides the atmosphere discharged to the joint pipe 60 to the exhaust equipment 95. Each of the pipe 153 for exhaust equipment and the return pipe 60A is connected to the tank 64. The exhaust equipment 95 is provided, for example, below a floor surface 161 of a factory or the like. The circulation system 6A further includes a drain pipe 152. The drain pipe 152 communicates with the internal space of the tank 64, and discharges the liquid received by the tank 64 to the outside. The pipe 153 for exhaust equipment connects to the tank 64 at a location higher than the opening of the drain pipe 152 facing the inside of the tank 64, and includes an opening facing the inside of the tank 64.

The return pipe 60A includes the vertical pipe 65 extending upward from the tank 64, and a horizontal pipe 66 connected to the front end of the vertical pipe 65 and extending in the horizontal direction above the substrate processing device group 10. In the example of FIG. 1, the air flow generator 82 is provided in the horizontal pipe 66. If the air flow generator 82 is provided in the horizontal pipe 66, the footprint of the substrate processing device 100 can be suppressed. The vertical pipe 65 is provided such that the flow of the atmosphere circulated by the air flow generator 82 can rise inside the vertical pipe 65 and at least part of the vertical pipe 65 is provided so as to be positioned on the upstream side of the flow of the atmosphere with respect to the air flow generator 82.

In upper walls of the chambers 121 of the respective substrate processing units 1, through holes through which a vertical pipe 67 to be described later can be inserted are provided at identical locations in top view. A front end of the horizontal pipe 66 extends above the through holes. The return pipe 60A further includes the vertical pipe 67 extending downward from the front end of the horizontal pipe 66 and passing through each through hole of each chamber 121. As a result, the vertical pipe 67 is sequentially introduced into the chambers 121 of the substrate processing units 1 in order from the top to the bottom. The gap between the through hole of each chamber 121 and the vertical pipe 67 is sealed. The return pipe 60A further includes a plurality of (four in the illustrated example) branch pipes 68. Each branch pipe 68 is connected to each section of the vertical pipe 67 located in an upper side in each chamber 121. Each branch pipe 68 horizontally extends above the splash guard 31 in each chamber 121. An upper opening 41 is formed in a section of each branch pipe 68 above the splash guard 31 so as to face the splash guard 31. The ULPA filter 71 is attached to the front end section of each branch pipe 68. The atmosphere in the chamber 121 discharged from the chamber 121 to the joint pipe 60 passes through the joint pipe 60, reaches the front end of the branch pipe 68, is purified by the ULPA filter 71, and is supplied into the chamber 121.

As described above, the joint pipe 60 includes the vertical pipe 65 extending in the top-bottom direction. In addition, the joint pipe 60 includes the lower opening 42 provided below the spin chuck 21 and facing the inside of the chamber 121, and the upper opening 41 provided above the spin chuck 21 and facing the inside of the chamber 121. In addition, the joint pipe 60 is disposed such that at least part of the joint pipe 60 from the lower opening 42 to the upper opening 41 passes outside the chamber 121. The return pipe 60A is a section of the joint pipe 60 ranging to the upper opening 41 from the downstream side of the flow of the atmosphere circulated by the air flow generator 82 with respect to the pipe 153 for exhaust equipment.

The air flow generator 82 circulates the atmosphere containing the specific gas F2 in the chamber 121 by discharging the atmosphere in the chamber 121 from the lower opening 42 to the joint pipe 60 to allow the atmosphere to pass through the joint pipe 60, thereby introducing the atmosphere again into the chamber 121 via the upper opening 41 so that the downflow D1 of the atmosphere occurs in the chamber 121. As the gas F2, for example, air is adopted. As the gas F2, for example, N2 gas may be adopted.

The circulation system 6A preferably further includes a filter 72 in the joint pipe 60. The filter 72 can remove a specific component contained in the processing liquid (processing fluid) L1 from the atmosphere discharged from the chamber 121 to the joint pipe 60. The filter 72 is preferably provided on the upstream side of the flow of the atmosphere circulated by the air flow generator 82 with respect to the air flow generator 82. The filter 72 is a filter 72 capable of removing the processing liquid L1 in a form of mist, that is, a liquid in a form of mist from the atmosphere; however, a filter which can also remove dust contained in the atmosphere to some extent is preferably selected. As the filter 72, for example, a mist filter for removing moisture in a droplet state (misty state), a chemical filter for removing a certain chemical substance contained in the processing fluid by a chemical reaction, or the like is adopted. For example, in a case where SC1 is adopted as the processing liquid, it is assumed that the joint pipe 60, the air flow generator 82, and the like are corroded by ammonia (alkali) contained in SC1. Therefore, a chemical filter for removing the alkaline atmosphere is preferably attached to the vertical pipe 65.

As described above, at least part of the vertical pipe 65 is provided so as to be positioned on the upstream side of the flow of the atmosphere with respect to the air flow generator 82, and the filter 72 is preferably provided in the part of the vertical pipe 65, that is, a section of the vertical pipe 65 on the upstream side of the flow of the atmosphere with respect to the air flow generator 82. In the atmosphere discharged from the chamber 121, the processing liquid (liquid) L1 in a form of mist is contained. The filter 72 can remove the processing liquid (liquid) L1 in a form of mist from the atmosphere discharged from the chamber 121. In addition, the filter 72 is preferably provided in a section of the vertical pipe 65, closer to the tank 64 than to the air flow generator 82.

The circulation system 6A further includes the introduction pipe 69 and a regulating valve 93. The introduction pipe 69 is a pipe that causes a supply source (not illustrated) of the specific gas F2 and the joint pipe 60 to communicate with each other and can introduce the gas F2 into the joint pipe 60. The introduction pipe 69 is preferably connected to a section of the joint pipe 60 on the downstream side of the flow of the atmosphere with respect to the filter 72. The regulating valve 93 is a valve which can adjust the flow rate of the gas F2 flowing through the introduction pipe 69. The regulating valve 93 can adjust the opening degree thereof under control of the controller 130.

Here, since the carrying robot has a movable part, the atmosphere in a robot chamber where the carrying robot exists is dirtier than the atmosphere in the chamber 121. It is not preferable that the atmosphere enters the chamber 121. Therefore, the substrate processing device 100 suppresses entrance of the dirty atmosphere into the chamber 121 from the robot chamber where the carrying robot exists by leaking the air in the chamber 121 to the robot chamber. Therefore, it is necessary to compensate for the air leaked into the robot chamber from the chamber 121. The substrate processing device 100 includes the introduction pipe 69 connected to the supply source of the specific gas F2 and the regulating valve 93 provided in the introduction pipe 69. Note that the regulating valve 93 may be an on-off valve that can only be fully closed and fully opened.

The circulation system 6A further includes the on-off valve mechanism 90 that allows one of the return pipe 60A and the pipe 153 for exhaust equipment to be in an open state and the other to be in a closed state. The on-off valve mechanism 90 includes a first on-off valve 91 and a second on-off valve 92. The first on-off valve 91 is provided in a section of the vertical pipe 65 on the upstream side of the flow of the atmosphere circulated by the air flow generator 82 with respect to the filter 72, and is provided so as to be able to open and close the vertical pipe 65. The second on-off valve 92 is provided so as to be able to open and close the pipe 153 for exhaust equipment.

The controller 130 performs opening and closing control of the on-off valve mechanism 90 so that one of the return pipe 60A and the pipe 153 for exhaust equipment is in the open state and the other is in the closed state. The opening and closing control is control for bringing the return pipe 60A into the open state and bringing the pipe 153 for exhaust equipment into the closed state when the required exhaust amount of the substrate processing device 100 exceeds the exhaust amount allocated to the substrate processing device 100 out of the exhaust amount of the exhaust equipment 95, and bringing the return pipe 60A into the closed state and bringing the pipe 153 for exhaust equipment into the open state when the required exhaust amount does not exceed the allocated exhaust amount.

The controller 130 previously stores the control information K2 input via an input device such as a keyboard (not illustrated) in the storage 12. The CPU 11 of the controller 130 acquires the control information K2 from the storage 12 and performs opening and closing control of the on-off valve mechanism 90 according to the control information K2.

The control information K2 is information in which, for example, the process of substrate processing that the substrate processing device 100 is capable of performing and the opening and closing state of the on-off valve mechanism 90 are correlated with each other so that desired opening and closing control of the on-off valve mechanism 90 can be executed. More specifically, for example, in the control information K2, a plurality of processes that can be performed by the substrate processing device 100 is classified into a process in which the exhaust amount allocated to the device is insufficient, that is, shortage of the exhaust amount allocated to the device is expected, and a process in which there is more than enough power that the exhaust equipment 95 requires.

In addition, for example, the control information K2 includes an index value corresponding to the exhaust amount allocated to the substrate processing device by the exhaust equipment 95 and an index value corresponding to the required exhaust amount of the substrate processing device. For example, these index values are acquired in advance by the controller 130 from the exhaust equipment 95 or the like and are stored in the storage 12. The controller 130 determines whether the exhaust amount allocated to the device according to the magnitude of the respective index values is greater than the required exhaust amount of the device, that is, whether or not the exhaust amount allocated to the device is insufficient. The controller 130 circulates the atmosphere through the joint pipe 60 in a case where the exhaust amount allocated to the device is insufficient.

Note that in a case where the time period during which the exhaust amount allocated to the device by the exhaust equipment 95 is insufficient with respect to the required exhaust amount of the device and the time period in which the exhaust amount is not insufficient can be predicted according to the operation schedule of the respective devices that discharge gas to the exhaust equipment 95, the controller 130 may perform the opening and closing control of the on-off valve mechanism 90 according to the operation schedule.

According to the substrate processing device 1 according to the present embodiment 1 configured as described above, the joint pipe 60 includes the lower opening 42 and the upper opening 41 each of which faces the inside of the chamber 121, and is disposed such that at least part thereof from the lower opening 42 to the upper opening 41 passes through the outside of the chamber 121. The air flow generator 82 provided in the joint pipe 60 circulates the atmosphere containing the specific gas in the chamber 121 by discharging the atmosphere in the chamber 121 from the lower opening 42 to the joint pipe 60 to allow the atmosphere to pass through the joint pipe 60, thereby introducing the atmosphere again into the chamber 121 via the upper opening 41 so that a downflow D1 of the atmosphere occurs in the chamber 121. Thus, the substrate processing device can discharge the atmosphere in the chamber 121 to the outside of the chamber 121 even if the substrate processing device is not connected to the external exhaust equipment 95. Therefore, the substrate processing device can sufficiently discharge the atmosphere in the chamber 121 even in a case where the exhaust amount allocated by the external exhaust equipment 95 is quite insufficient compared with the required exhaust amount.

In addition, according to the substrate processing device according to the present embodiment 1, the substrate processing device further includes the filter 72 provided in the joint pipe 60 and capable of removing the specific component contained in the processing fluid from the atmosphere discharged from the chamber 121 into the joint pipe 60. Therefore, the atmosphere discharged from the chamber 121 to the joint pipe 60 is purified by the filter 72 and is then circulated into the chamber 121 again. As a result, the quality of substrate processing can be improved.

Further, according to the substrate processing device according to the present embodiment 1, the filter 72 is provided on the upstream side of the flow of the atmosphere circulated by the air flow generator 82 with respect to the air flow generator 82. Therefore, since the atmosphere purified by the filter 72 is sent to the air flow generator 82, deterioration of the air flow generator 82 due to the component of the processing fluid mixed in the atmosphere can be suppressed.

In addition, the substrate processing device according to the present embodiment 1, the processing fluid contains the specific liquid, and the filter 72 is capable of removing the liquid in the form of mist from the atmosphere and is provided in the section of the vertical pipe 65 included in the joint pipe 60, on the upstream side of the flow of the atmosphere with respect to the air flow generator 82. Therefore, the liquid in the form of mist in the atmosphere separated by the filter 72 easily drips downward along the vertical pipe 65.

According to the substrate processing device according to the present embodiment 1, since the tank 64 is provided at the lower end in the vertical direction of the joint pipe 60, drops (large droplets) of the specific liquid discharged to the joint pipe 60 together with the atmosphere in the chamber 121 flow into the tank 64 along an inner wall of the joint pipe 60 and are received by the tank 64. The liquid in the form of mist mixed with the atmosphere and is discharged to the joint pipe 60 flows from the tank 64 to the vertical pipe 65 together with the atmosphere, but the liquid is removed by the filter 72. Therefore, on the downstream side of the flow of the atmosphere with respect to the filter 72, the atmosphere from which both the liquid in the form of drops and the liquid in the form of mist are removed flows. Therefore, deterioration of the air flow generator 82 due to the component of the processing fluid is efficiently suppressed.

In addition, according to the substrate processing device according to the present embodiment 1, the filter 72 is provided in the section of the vertical pipe 65, closer to the tank 64 than to the air flow generator 82. When the liquid in the form of mist in the processing fluid is separated from the atmosphere by the filter 72 and becomes drops, and the drops drip down along the inner peripheral surface of the vertical pipe 65, if many drops adhere to the inner peripheral surface, resistance that the atmosphere flowing through the vertical pipe 65 receives increases. However, if the filter 72 is closer to the tank 64 than to the air flow generator 82 in the vertical pipe 65, the range where drops adhere can be made smaller, so that the flow of the atmosphere in the vertical pipe 65 becomes smooth.

In addition, the substrate processing device according to the present embodiment 1, the substrate processing device further includes: the introduction pipe 69 that causes the supply source of the specific gas F2 contained in the atmosphere in the chamber 121 and the joint pipe 60 to communicate with each other so as to be capable of introducing the gas F2 into the joint pipe 60; and the regulating valve 93 that is capable of regulating the flow rate of the gas F2 flowing through the introduction pipe 69. Therefore, even in a case where the gas F2 leaks from the chamber 121 to the outside, the gas F2 can be filled in the chamber 121 via the joint pipe 60, the introduction pipe 69, and the regulating valve 93.

In addition, according to the substrate processing device according to the present embodiment 1, the filter 72 is provided on the upstream side of the flow of the atmosphere circulated by the air flow generator 82 with respect the air flow generator 82, and the introduction pipe 69 is connected to the section of the joint pipe 60 on the downstream side of the flow of the atmosphere with respect to the filter 72. Therefore, it is possible to suppress mixing of the specific component of the processing fluid into the specific gas F2 introduced into the joint pipe 60 from the introduction pipe 69, the processing fluid being mixed with the atmosphere and discharged to the joint pipe 60 from the chamber 121, and to suppress deterioration of the air flow generator 82 due to the component of the processing fluid.

In addition, the substrate processing device according to the present embodiment 1, the substrate processing device further includes the on-off valve mechanism 90 that brings one of the return pipe 60A and the pipe 153 for exhaust equipment into the open state and brings the other into the closed state. Therefore, the substrate processing device can selectively perform circulation of the atmosphere discharged from the chamber 121 through the return pipe 60A into the chamber 121 and discharge of the atmosphere to the exhaust equipment 95 via the pipe 153 for exhaust equipment.

In addition, according the substrate processing device according to the present embodiment 1 configured as described above, the controller 130 performs control for circulating the atmosphere discharged from the chamber 121 into the chamber 121 via the return pipe 60A when the required exhaust amount of the substrate processing device exceeds the exhaust amount allocated to the substrate processing device out of the exhaust amount of the external exhaust equipment 95 and performs control for discharging the atmosphere into the exhaust equipment 95 via the pipe 153 for exhaust equipment when the required exhaust amount does not exceed the allocated exhaust amount. Therefore, the substrate processing device can circulate the atmosphere only in a case where the exhaust amount allocated to the device by the exhaust equipment 95 is insufficient.

In addition, according to the substrate processing device according to the present embodiment 1, the control information K2 includes information in which the process of substrate processing that can be executed by the substrate processing device and the opening and closing state of the on-off valve mechanism 90 are correlated with each other so that the opening and closing control can be executed. Therefore, the controller 130 can perform control for circulating the atmosphere in the case of performing the process of the substrate processing in which the exhaust amount allocated to the device by the exhaust equipment 95 is insufficient, and can perform control for discharging the atmosphere to the exhaust equipment 95 in the case of executing the process of the substrate processing in which the exhaust amount is not insufficient.

According to the substrate processing device according to the present embodiment 1, the control information K2 includes the index value corresponding to the exhaust amount allocated to the substrate processing device by the exhaust equipment 95 and the index value corresponding to the required exhaust amount of the substrate processing device. Therefore, the controller 130 can make a determination as to whether or not the exhaust amount allocated to the substrate processing device by the exhaust equipment 95 is insufficient compared with the required exhaust amount of the substrate processing device, and can perform the opening and closing control of the on-off valve mechanism 90 according to the determination.

In addition, according the substrate processing device according to the present embodiment 1, the on-off valve mechanism 90 includes: the first on-off valve 91 that is provided at the section of the vertical pipe 65 on the upstream side of the flow of the atmosphere circulated by the air flow generator 82 with respect to the filter 72 and is capable of opening and closing the vertical pipe 65; and the second on-off valve 92 capable of opening and closing the pipe 153 for exhaust equipment. Therefore, by opening one of the first on-off valve 91 and the second on-off valve 92 and closing the other, the substrate processing device can selectively perform circulation of the atmosphere discharged from the chamber 121 into the chamber 121 via the return pipe 60A and discharge of the atmosphere to the exhaust equipment 95 via the pipe 153 for exhaust equipment 95.

In addition, according the substrate processing device according to the present embodiment 1, the substrate processing device further includes: the introduction pipe 69 that causes the supply source of the specific gas F2 and the vertical pipe 65 to communicate with each other so as to be capable of introducing the specific gas F2 into the vertical pipe 65; and the regulating valve 93 that is capable of regulating the flow rate of the gas F2 flowing through the introduction pipe 69, in which the introduction pipe 69 is connected to the section of the joint pipe 60 on the downstream side of the flow of the atmosphere circulated by the air flow generator 82 with respect to the filter 72. Therefore, it is possible to suppress mixing of the specific component of the processing fluid into the specific gas F2 introduced into the joint pipe 60 from the introduction pipe 69, the processing fluid being mixed with the atmosphere and discharged to the joint pipe 60 from the chamber 121, and to suppress deterioration of the air flow generator 82 due to the component of the processing fluid.

<4. Substrate Processing Device 102>

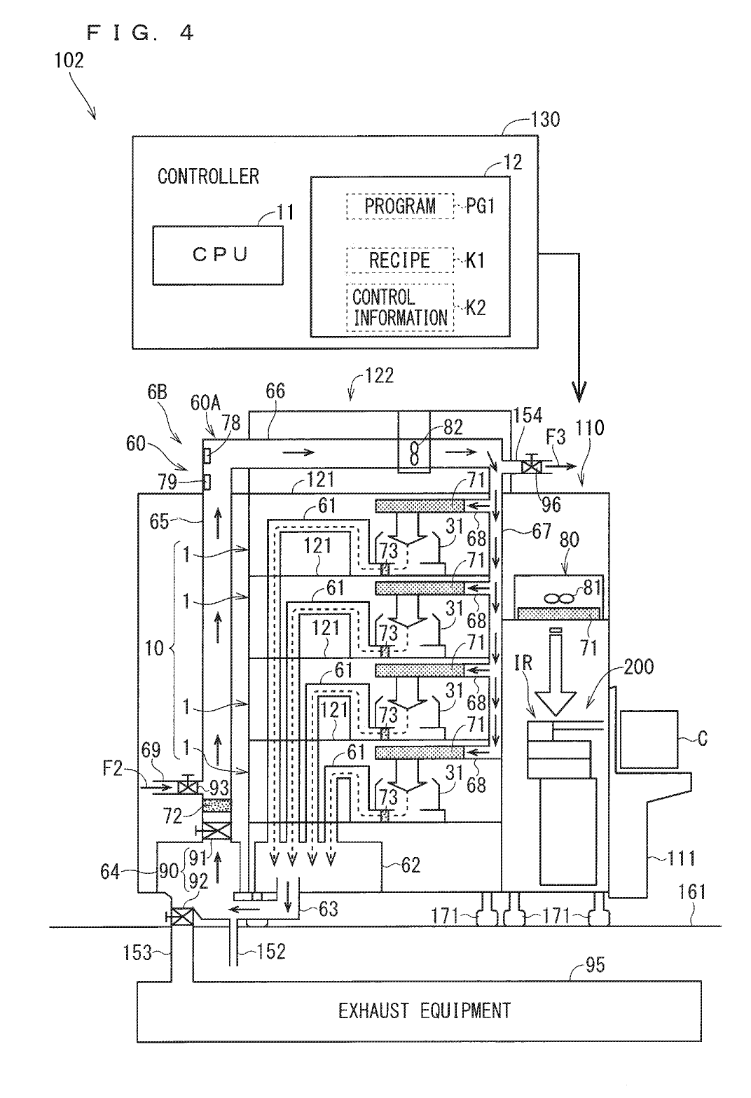

The configuration of a substrate processing device 102 will be described with reference to FIG. 4. FIG. 4 is a side cross-sectional view schematically illustrating the substrate processing device 102 according to Embodiment 2.

The substrate processing device 102 is a system for processing a substrate W such as a semiconductor wafer, similarly to the substrate processing device 100 according to Embodiment 1.

The substrate processing device 102 is configured similarly to the substrate processing device 100 except that a processing cell 122 is provided in lieu of the processing cell 120 of the substrate processing device 100 according to Embodiment 1. That is, the substrate processing device 102 includes an indexer cell 110, a processing cell 122, and a controller 130. The controller 130 collectively controls respective operation mechanisms and the like included in the plurality of cells 110, 122. The controller 130 also controls a substrate carrying device 200 included in the plurality of cells 110, 122.

<Processing Cell 122>

The processing cell 122 is a cell for processing the substrate W. The processing cell 122 is configured similarly to the processing cell 120 except that a circulation system 6B is provided in lieu of the circulation system 6A of the processing cell 120. That is, the processing cell 122 includes a plurality of substrate processing units 1, a circulation system 6B, and a carrying robot (not illustrated) for carrying the substrates W into and out of the plurality of substrate processing units 1. The circulation system 6B discharges an atmosphere in the chamber 121 of each substrate processing unit 1 from a chamber 121 and circulates the atmosphere again into the chamber 121. The carrying robot of the processing cell 122 is configured similarly to the carrying robot of the processing cell 120. The carrying robot and the transfer robot IR are the substrate carrying device 200.

<5. Configuration of Circulation System 6B>

The circulation system 6B discharges the atmosphere in the chamber 121 (more specifically, in the splash guard 31) of the substrate processing unit 1 from the substrate processing unit 1 and introduces the atmosphere again into the chamber 121 to circulate the atmosphere in the chamber 121.

The circulation system 6B is configured similarly to the circulation system 6A of the processing cell 120 except that the circulation system 6B further includes an exhaust pipe 154 and a regulating valve 96, and further includes a hygrometer 78, a concentration meter 79, and a chemical filter 73. That is, the circulation system 6B includes a joint pipe 60 and an air flow generator 82 provided in the joint pipe 60.

The air flow generator 82 circulates the atmosphere containing a gas F2 in the chamber 121 by discharging the atmosphere in the chamber 121 from a lower opening 42 to the joint pipe 60 to allow the atmosphere to pass through the joint pipe 60, thereby introducing the atmosphere again into the chamber 121 via an upper opening 41 so that a downflow D1 of the atmosphere occurs in the chamber 121.

Similarly to the joint pipe 60 of the circulation system 6A, the joint pipe 60 of the circulation system 6B includes a plurality of (four in the example of FIG. 4) pipes 61, a tank 62, a pipe 63, a tank 64, and a return pipe 60A.

The return pipe 60A includes the vertical pipe 65 extending upward from the tank 64, and a horizontal pipe 66 connected to the front end of the vertical pipe 65 and extending in the horizontal direction above the substrate processing device group 10. In the example of FIG. 4, the air flow generator 82 is provided in the horizontal pipe 66.

The return pipe 60A further includes a vertical pipe 67. The vertical pipe 67 extends downward from a front end of the horizontal pipe 66 and is introduced into the chamber 121 of the uppermost substrate processing unit 1 and then is sequentially introduced into the chambers 121 of the substrate processing units 1 from the top to the bottom. The return pipe 60A further includes a plurality of (four in the example of FIG. 4) branch pipes 68 branching off from the vertical pipe 67 and horizontally extending above the splash guard 31 in each chamber 121.

The exhaust pipe 154 communicates with and connects to the joint pipe 60. The exhaust pipe 154 extends from the joint pipe 60 to the outside of the substrate processing device 102, and a front end of the exhaust pipe 154 opens to the outside space. The exhaust pipe 154 discharges part of the atmosphere circulated by the air flow generator 82 to the outside of the substrate processing device 102 as a flow F3 of the atmosphere.

The regulating valve 96 is provided in the exhaust pipe 154. The regulating valve 96 is a valve which can regulate the flow rate of the flow F3 of the atmosphere. The opening degree of the regulating valve 96 is set to an arbitrary opening degree between a closed state and an open state under control of the controller 130. The flow rate of the flow F3 of the atmosphere discharged by the exhaust pipe 154 changes according to the opening degree of the regulating valve 96. In a case where the atmosphere is not discharged from the exhaust pipe 154, the controller 130 closes the regulating valve 96.

The exhaust pipe 154 is preferably connects to the joint pipe 60 on the downstream side of the flow of the atmosphere circulated by the air flow generator 82 with respect to the air flow generator 82 and on the upstream side with respect to the location where the branch pipe 68 on the most upstream side branches off from the vertical pipe 67. Thus, the flow rate of the atmosphere distributed to each chamber 121 can be adjusted by one exhaust pipe 154. In the example of FIG. 4, the exhaust pipe 154 connects to part of a section where a section of the horizontal pipe 66 on the downstream side of the flow of the atmosphere with respect to the air flow generator 82 and a section of the vertical pipe 67 on the upstream side with respect to the branch pipe 68 on the most upstream side are combined (more specifically, for example, a joint section between the horizontal pipe 66 and the vertical pipe 67).

Each pipe 61 of the joint pipe 60 extends from below each splash guard 31 in each chamber 121, passes through each chamber 121, and is disposed outside each chamber 121. A front end of each pipe 61 is connected to the upper part of the tank 62. The atmosphere in the space surrounded by each splash guard 31, that is, the atmosphere in each chamber 121 is discharged through each lower opening 42 of each pipe 61 to each pipe 61, that is, the joint pipe 60. In the joint pipe 60 (pipe 61), a flow F1 of the discharged atmosphere is formed.

The substrate processing device 102 further includes a chemical filter 73 in each pipe 61. Each chemical filter 73 removes a specific chemical substance from the atmosphere discharged from each chamber 121 to each pipe 61 by a chemical reaction. In a case where a chemical solution is used as a processing liquid (processing fluid) L1, the chemical substance is contained in the atmosphere as a mist or the like (mist or gas) which originates from the chemical solution.

The substrate processing device 102 further includes, in the joint pipe 60, the hygrometer 78 for measuring the humidity in the atmosphere circulating through the joint pipe 60, and the concentration meter 79 for measuring the concentration of a specific gas in the atmosphere. The hygrometer 78 and the concentration meter 79 are electrically connected to the controller 130, and measured values of the hygrometer 78 and the concentration meter 79 are sent to the controller 130. The controller 130 can control the substrate processing device 102 according to the measured values. The hygrometer 78 is preferably provided on the downstream side of the flow of the atmosphere circulated by the air flow generator 82 with respect to a filter 72.

<6. Regarding Control of Flow Rate of Downflow or the like in Chamber>

In a case where the on-off valve mechanism 90 brings the return pipe 60A into the open state and the pipe 153 for exhaust equipment into the closed state and thus the atmosphere discharged to the joint pipe 60 circulates through the circulation system 6B, an air flow of the atmosphere is generated in the joint pipe 60 when the air flow generator 82 is driven, and the regulating valve 96 of the exhaust pipe 154 receives pressure due to the air flow. Therefore, if the controller 130 increases the opening degree of the regulating valve 96, the flow rate of the flow F3 of the atmosphere flowing out from the joint pipe 60 through the exhaust pipe 154 to the outside of the substrate processing device 102 increases. In contrast, if the controller 130 reduces the opening degree of the regulating valve 96, the flow rate of the flow F3 of the atmosphere decreases.

The air flow generator 82 generates a flow of the atmosphere having a constant flow rate, for example, near the air flow generator 82 in the joint pipe 60. If the flow rate of the flow F3 of the atmosphere flowing out from the joint pipe 60 through the exhaust pipe 154 to the outside of the substrate processing device 102 increases, the flow rate of the downflow D1 of the atmosphere passing through the joint pipe 60 and is introduced into the chamber 121 through the upper opening 41 decreases. In contrast, if the flow rate of the flow F3 of the atmosphere decreases, the flow rate of the downflow D1 increases.

The flow rate of the atmosphere in the splash guard 31 of the chamber 121 greatly affects the quality of substrate processing performed by each substrate processing unit 1. If the flow rate of the downflow D1 of the atmosphere increases, the flow rate of the atmosphere in the splash guard 31 also increases. If the flow rate of the downflow D1 decreases, the flow rate of the atmosphere in the splash guard 31 also decreases.

Therefore, the substrate processing device 102 stores in advance the opening degree of the regulating valve 96 with which the desired flow rate of the downflow D1 is obtained as control information K2 for each executable process. According to a recipe K1 and the control information K2, the controller 130 acquires the opening degree of the regulating valve 96 corresponding to the process to be actually performed, and controls the regulating valve 96 such that the regulating valve 96 is at the opening degree. Note that as stated in the description of the substrate processing device 100, the control information K2 also includes, for example, information in which the process of substrate processing that can be executed by the substrate processing device 100 and the opening and closing state of the on-off valve mechanism 90 are correlated with each other so that desired opening and closing control of the on-off valve mechanism 90 can be executed.

In addition, in a case where the processing liquid L1 used by a substrate processing mechanism A1 is a chemical solution, it is not preferable from the viewpoint of environment that the atmosphere containing mists or the like (mists or gas) originating from the chemical solution leaks from the chamber 121 to the outside of the substrate processing device 102. In contrast, in a case where the processing liquid L1 is pure water or functional water, even if the atmosphere containing mists or the like of them leaks from the chamber 121 to the outside of the substrate processing device 102, it does not become a serious problem. In the case where the processing liquid L1 is pure water or functional water, since dust or the like accumulated in the chamber 121 can be discharged to the outside of the chamber 121 together with the atmosphere, it is rather preferable that the atmosphere in the chamber 121 leaks to the outside of the substrate processing device 102 from the chamber 121.

As described above, from the viewpoint of environment, that is, as to whether leakage of the atmosphere in the chamber 121 (splash guard 31) to the outside of the chamber 121 becomes a problem or does not become a serious problem, it is necessary to adjust the magnitude relationship between the flow rate of the downflow D1 of the atmosphere to be introduced into the chamber 121 via the upper opening 41 and the flow rate of the flow F 1 of the atmosphere discharged from the splash guard 31 through the lower opening 42 to the joint pipe 60 (pipe 61).

If the flow rate of the downflow D1 flowing into the chamber 121 is greater than the flow rate of the flow F1 of the atmosphere discharged from the chamber 121, the pressure inside the chamber 121 is higher than each of the pressure outside the chamber 121 and the pressure inside of the pipe 61 of the joint pipe 60, and therefore the atmosphere in the chamber 121 is easily discharged to the outside of the chamber 121 and to the pipe 61. Therefore, for example, in a case where the processing liquid L1 is pure water, functional water, or the like, it is preferable that the substrate processing device 102 reduces the opening degree of the regulating valve 96 so that the flow rate of the downflow D1 is greater than the flow rate of the flow F1 of the atmosphere.

In contrast, if the flow rate of the downflow D1 is smaller than the flow rate of the flow F 1 of the atmosphere to be discharged, the pressure inside the chamber 121 becomes lower than each of the pressure outside the chamber 121 and the pressure inside the pipe 61 of the joint pipe 60, and therefore the atmosphere of the chamber 121 is less likely to be discharged to the outside of the chamber 121 and to the pipe 61. Therefore, for example, in a case where the processing liquid L1 is a chemical solution, it is preferable that the substrate processing device 102 increases the opening degree of the regulating valve 96 so that the flow rate of the downflow D1 is smaller than the flow rate of the flow F1 of the atmosphere.

The substrate processing device 102 also stores as control information K2 the correspondence relationship between each process of substrate processing that can be executed by the substrate processing device 100 and the preferable opening degree of the regulating valve 96 in the storage 12. By referring to the recipe K1 and the control information K2, the controller 130 acquires the opening degree of the regulating valve 96 corresponding to the process to be executed, and controls the regulating valve 96 such that the regulating valve 96 is at the acquired opening degree.

As described above, the substrate processing device 102 includes the exhaust pipe 154 provided in the joint pipe 60, and the regulating valve 96 is provided in the exhaust pipe 154. Therefore, according to the substrate processing device 102, by adjusting the opening degree of the regulating valve 96 and adjusting the flow rate of the flow F3 of the atmosphere passing through the exhaust pipe 154 and discharged, it is possible to easily adjust the flow rate of the downflow D1 of the atmosphere introduced into the chamber 121 via the upper opening 41.

In a case where the substrate processing device 102 adjusts the opening degree of the regulating valve 93 to change the flow rate of the gas F2 passing through the introduction pipe 69 and introduced into the joint pipe 60, the flow rate of the downflow D1 changes depending on the balance between the flow rate of the gas F2 and the flow rate of the flow F3 of the atmosphere discharged from the exhaust pipe 154.

Therefore, in the substrate processing device 102, it is more preferable that the correspondence relationship between each process of substrate processing that can be executed by the substrate processing device 100 and the opening degrees of the regulating valves 93, 96 preferable for each process is acquired in advance and stored in the storage 12 as the control information K2, and the controller 130 refers to the recipe K1 and the control information K2 to acquire the opening degrees of the regulating valves 93, 96 corresponding to the process to be executed, and controls the regulating valves 93, 96 so that the acquired opening degrees are obtained.

<7. Regarding Control of Humidity and Oxygen Concentration in Atmosphere>

In a case where the substrate processing unit 1 uses, for example, pure water as the processing liquid L1 to perform processing, the atmosphere discharged from the chamber 121 to the joint pipe 60 contains a large amount of moisture in a droplet state (misty state). In a case where the on-off valve mechanism 90 brings the return pipe 60A into the closed state and the pipe 153 for exhaust equipment into the open state, the atmosphere discharged from the chamber 121 to the joint pipe 60 passes through the pipe 153 for exhaust equipment and is discharged to the exhaust equipment 95. Therefore, even if the discharged atmosphere contains a large amount of moisture, it does not become a serious problem.

However, in a case where the on-off valve mechanism 90 brings the return pipe 60A into the open state and the pipe 153 for exhaust equipment into the closed state and thus the atmosphere discharged to the joint pipe 60 circulates through the circulation system 6B, humidity of the circulating atmosphere may be higher than a specific reference value determined for the process. Therefore, when the humidity in the atmosphere measured by the hygrometer 78 becomes higher than the reference value, the controller 130 of the substrate processing device 102 increases the opening degree of the regulating valve 93 and introduces more dry air or the like through the introduction pipe 69 into the joint pipe 60. As a result, the humidity in the atmosphere can be lowered. In contrast, in a case where the humidity in the atmosphere is lower than the specific reference value, the controller 130 can increase the humidity in the atmosphere by reducing the opening degree of the regulating valve 93.

When the substrate processing unit 1 processes the substrate W, for example, nitrogen gas or the like may be injected as a purge gas. In this case, in a case where the on-off valve mechanism 90 brings the return pipe 60A into the open state and brings the pipe 153 for exhaust equipment into the closed state and thus the atmosphere discharged to the joint pipe 60 circulates through the circulation system 6B, the concentration of the purge gas may increase and the oxygen concentration may decrease in the chamber 121 as time passes, and thus the inside of the chamber 121 may become a dangerous environment for an operator. Therefore, the controller 130 of the substrate processing device 102 measures the concentration of a specific gas (for example, oxygen or nitrogen gas) in the atmosphere measured by the concentration meter 79. For example, in a case where the oxygen concentration measured by the concentration meter 79 is lower than a specific reference value, the controller 130 increases the opening degree of the regulating valve 93 to introduce more fresh air or the like containing much oxygen from the introduction pipe 69 to the joint pipe 60. Thus, the oxygen concentration in the atmosphere circulating through the circulation system 6B can be increased to the specific reference value or higher.

The substrate processing device 102 may not control the humidity or the oxygen concentration in the atmosphere of the chamber 121. In this case, the substrate processing device 102 may not include the hygrometer 78 or the concentration meter 79.

<8. Measures to be Taken when Processing Liquid Containing Specific Chemical Substance is Used>

In a case where a chemical solution having strong corrosive action is used as the processing liquid L1, the atmosphere in the chamber 121 containing mists of the chemical solution flows into the joint pipe 60, and the path of the atmosphere in the joint pipe 60 may corrode. If the joint pipe 60 corrodes, rust or the like may circulate through the circulation system 6B and flow into the chamber 121.

If the atmosphere in the chamber where the chemical-solution processing is performed on the substrate is discharged from the chamber by the circulation system and is introduced into the chamber again, the substrate may be contaminated by the atmosphere including the mists or the like originating from the chemical solution. For this reason, in a conventional substrate processing device that houses a substrate in a chamber and performs chemical-solution processing, a configuration in which the atmosphere in the chamber is circulated using the circulation system is not adopted.

However, according to the substrate processing device 102, also in a case where the atmosphere of the chamber 121 is circulated by the circulation system 6B, the chemical filter 73 is provided in each pipe 61 to remove a chemical substance causing corrosion. Therefore, corrosion of the joint pipe 60 can be suppressed and contamination of the substrate W by the chemical substance in the atmosphere introduced again into the chamber 121 can be suppressed.

It is preferable that the chemical substance is removed as soon as possible after the atmosphere has flowed into the joint pipe 60 from the chamber 121. Therefore, it is preferable that each chemical filter 73 is provided as close as possible to the lower opening 42 in each pipe 61. In a case where the substrate processing mechanism A1 does not use a chemical solution having strong corrosiveness as the processing liquid L1 but uses only a liquid having low corrosiveness such as pure water or functional water, the substrate processing device 102 may not include the chemical filter 73.

Incidentally, in the substrate processing device 102, a case is assumed where the processing liquid L1 is a chemical solution, the concentration of the chemical substance remaining without being removed in the atmosphere that has passed through the chemical filter 73 exceeds the concentration allowed from the viewpoint of the quality of substrate processing.

Therefore, in the substrate processing device 102, with respect to each processing liquid assumed to be used as the processing liquid L1, it is checked in advance whether or not the specific chemical substance can be removed from the atmosphere containing mists or the like originating from the processing liquid by the chemical filter 73 to a level satisfying a specific quality standard.

According to the check result, it is determined that a processing liquid from which the chemical substance is removed to a level satisfying the quality standard can be circulated by the circulation system 6B, and it is determined that a processing liquid from which the chemical substance is not removed to the level satisfying the quality standard will not be circulated by the circulation system 6B.

Specifically, for example, it is determined that functional water such as CO₂ water or pure water is suitable for circulation by the circulation system 6B, and it is determined that a chemical solution such as SC1 or SC2 is not suitable for circulation by the circulation system 6B.

According to the determination result, the substrate processing device 102 stores in the storage 12 in advance as the control information K2 the correspondence relationship between each processing liquid L1 and propriety of circulation of the atmosphere in the chamber 121 by the circulation system 6B.

The controller 130 of the substrate processing device 102 determines whether or not the processing liquid L1 to be used is suitable for circulation of the atmosphere in the chamber 121 by the circulation system 6B, according to the recipe K1 and the control information K2. In a case where the processing liquid L1 is not suitable for the circulation, the controller 130 controls the on-off valve mechanism 90 such that the return pipe 60A is brought into the closed state and the pipe 153 for exhaust equipment is brought into the open state to discharge the atmosphere which has been discharged to the joint pipe 60 to the exhaust equipment 95 without circulating the atmosphere by the circulation system 6B.

In a case where the processing liquid L1 is suitable for the circulation, the controller 130 controls the on-off valve mechanism 90 such that the return pipe 60A is brought into the open state and the pipe 153 for exhaust equipment is brought into the closed state to circulate the atmosphere discharged to the joint pipe 60 by the circulation system 6B.

Therefore, according to the substrate processing device 102, in the case of using the processing liquid L1 containing a chemical substance which is not sufficiently removed by the chemical filter 73 as a component, the atmosphere in the chamber 121 is not circulated by the circulation system 6B. As a result, the processing quality of the substrate W is improved.

In the substrate processing device 102 of FIG. 4, since the circulation system 6B is provided for the substrate processing device group 10 having a plurality of (four) substrate processing units 1, a determination on propriety of circulation of the atmosphere by the circulation system 6B is made for the substrate processing device group 10. The determination is preferably made for each process performed by the substrate processing device 102.

<9. Another Embodiment of Substrate Processing Unit 1>

The substrate processing unit 1 (substrate processing mechanism A1) may also be a processing unit (so-called a spin scrubber) which performs scrub cleaning processing (physical cleaning processing of cleaning a front surface of a substrate by physical cleaning action) of bringing a brush, a sponge or the like into contact with the front surface of the rotating substrate W to brush the front surface while supplying a cleaning liquid such as pure water, thereby mechanically (physically) removing contaminants such as particles adhering to the front surface of the substrate W.

In a case where the substrate processing unit 1 is a spin scrubber, the substrate processing unit 1 uses, for example, pure water, functional water (CO₂ water or the like), or the like as a processing liquid L1 to perform the scrub cleaning processing and rinsing processing of the substrate W. The substrate processing unit 1 removes particles or the like on the substrate W by performing the scrub cleaning processing, and then washes away the particles or the like remaining on the substrate W by performing the rinsing processing.

In a case where the substrate processing unit 1 performs the scrub cleaning processing or the rinsing processing using pure water or functional water as the processing liquid L1, since the substrate processing unit 1 does not use a chemical solution such as SC1, mists originating from the chemical solution are not generated by the substrate processing performed by the substrate processing unit 1. Therefore, even in a case where the substrate processing unit 1 uses a circulation system 6B to circulate an atmosphere in a chamber 121 and to introduce again the atmosphere into the chamber 121, the likelihood that the substrate W will be contaminated by the atmosphere can be reduced.

Although the present invention has been illustrated and described in detail, the above description is illustrative and not restrictive in all aspects. Therefore, within the scope of the present invention, the embodiments can be appropriately modified and omitted.

### EXPLANATION OF REFERENCE SIGNS

100, 102: substrate processing device
1: substrate processing unit
121: chamber
A1: substrate processing mechanism
41: upper opening
42: lower opening
60: joint pipe
69: introduction pipe
6A, 6B: circulation system
73: chemical filter
78: hygrometer
79: concentration meter
82: air flow generator
93, 96: regulating valve
130: controller
154: exhaust pipe
11: CPU
21: spin chuck (holding member)
51: nozzle
D1: downflow
L1: processing liquid (processing fluid)
a1: rotary axis
c1: center

1. A substrate processing device comprising:
a chamber;
a substrate processing mechanism that has a holding member capable of holding a substrate in a substantially horizontal state, is housed in said chamber, and discharges processing fluid onto the substrate held by said holding member to process said substrate;
a joint pipe that has a lower opening provided below said holding member and facing an inside of said chamber, and an upper opening provided above said holding member and facing the inside of said chamber, and is disposed such that at least part of the joint pipe from said lower opening to said upper opening passes through an outside of said chamber; and
an air flow generator that is provided in said joint pipe,
wherein said air flow generator circulates an atmosphere containing a specific gas in said chamber by discharging said atmosphere in said chamber from said lower opening to said joint pipe to allow said atmosphere to pass through said joint pipe, thereby introducing said atmosphere again into said chamber via said upper opening so that a downflow of said atmosphere occurs in said chamber.

2. The substrate processing device according to claim 1, further comprising a filter that is provided in said joint pipe and is capable of removing a specific component contained in said processing fluid from said atmosphere discharged from said chamber into said joint pipe.

3. The substrate processing device according to claim 2, wherein said filter is provided on an upstream side of a flow of said atmosphere circulated by said air flow generator with respect to said air flow generator.

4. The substrate processing device according to claim 3,
wherein said processing fluid contains a specific liquid,
said joint pipe includes a vertical pipe extending in a top-bottom direction,
said vertical pipe is provided such that the flow of said atmosphere circulated by said air flow generator is capable of rising inside said vertical pipe and at least part of said vertical pipe is located on the upstream side of the flow of said atmosphere with respect to said air flow generator, and
said filter is provided in said at least part of said vertical pipe and is capable of removing said liquid in a form of mist from said atmosphere.

5. The substrate processing device according to claim 4,
wherein said joint pipe includes a tank provided at a lower end in a vertical direction,
said tank is provided so as to be capable of receiving said liquid mixed with said atmosphere and discharged from said chamber to said joint pipe, and
said vertical pipe extends upward from said tank such that an internal space of said vertical pipe and an internal space of said tank communicate with each other.

6. The substrate processing device according to claim 5, wherein said filter is provided in a section of said vertical pipe, closer to said tank than to said air flow generator.

7. The substrate processing device according to claim 1, further comprising:
an introduction pipe that causes a supply source of said specific gas and said joint pipe to communicate with each other so as to be capable of introducing said gas into said joint pipe; and
a regulating valve that is capable of regulating a flow rate of said gas flowing through said introduction pipe.

8. The substrate processing device according to claim 7, further comprising a filter that is provided in said joint pipe and is capable of removing a specific component contained in said processing fluid from said atmosphere discharged from said chamber into said joint pipe,
wherein said filter is provided on an upstream side of a flow of said atmosphere circulated by said air flow generator with respect to said air flow generator, and
wherein said introduction pipe is connected to a section of said joint pipe, on a downstream side of the flow of said atmosphere with respect to said filter.

9. The substrate processing device according to claim 1
further comprising a pipe for exhaust equipment that branches off from said joint pipe to cause said joint pipe to communicate with external exhaust equipment, and guides said atmosphere discharged to said joint pipe to said exhaust equipment, and
further comprising an on-off valve mechanism that is capable of bringing one of a return pipe and said pipe for exhaust equipment into an open state and bringing the other into a closed state,
when the return pipe is defined by a section of said joint pipe ranging from a downstream side of a flow of said atmosphere circulated by said air flow generator with respect to said pipe for exhaust equipment to said upper opening.

10. The substrate processing device according to claim 9, further comprising a controller that performs opening and closing control of said on-off valve mechanism so that one of said return pipe and said pipe for exhaust equipment is in the open state and the other is in the closed state,
wherein said opening and closing control is control for bringing said return pipe into the open state and bringing said pipe for exhaust equipment into said closed state when a required exhaust amount of said substrate processing device exceeds an exhaust amount allocated to said substrate processing device out of an exhaust amount of said exhaust equipment and for bringing said return pipe into the closed state and bringing said pipe for exhaust equipment into the open state when said required exhaust amount does not exceed said exhaust amount allocated.

11. The substrate processing device according to claim 10,
wherein said controller performs said opening and closing control according to control information acquired in advance, and
said control information includes information in which a process of substrate processing that said substrate processing device is capable of executing and an opening and closing state of said on-off valve mechanism are correlated with each other so that said opening and closing control can be executed.

12. The substrate processing device according to claim 10,
wherein said controller performs said opening and closing control according to control information acquired in advance, and
said control information includes an index value corresponding to an exhaust amount allocated to said substrate processing device by said external exhaust equipment and an index value corresponding to the required exhaust amount of said substrate processing device.

13. The substrate processing device according to claim 9,
wherein said processing fluid contains a specific liquid,
said joint pipe includes a tank provided at a lower end of said joint pipe in a vertical direction,
said tank is provided so as to be capable of receiving said liquid mixed with said atmosphere and discharged from said chamber into said joint pipe,
said pipe for exhaust equipment and said return pipe are connected to said tank,
said return pipe includes a vertical pipe extending upward from said tank,
said vertical pipe is provided so that the flow of said atmosphere circulated by said air flow generator is capable of rising inside said vertical pipe and at least part of said vertical pipe is located on an upstream side of the flow of said atmosphere with respect to said air flow generator, and
the substrate processing device further comprising a filter that is provided in said at least part of said vertical pipe and is capable of removing said liquid in a form of mist from said atmosphere,
wherein said on-off valve mechanism includes a first on-off valve that is provided at a section of said vertical pipe, on an upstream side of the flow of said atmosphere circulated by said air flow generator with respect to said filter and is capable of opening and closing the vertical pipe, and a second on-off valve capable of opening and closing the pipe for exhaust equipment.

14. The substrate processing device according claim 13, further comprising:
an introduction pipe that causes a supply source of said specific gas and said vertical pipe to communicate with each other so as to be capable of introducing said gas into said vertical pipe; and
a regulating valve that is capable of regulating a flow rate of said gas flowing through said introduction pipe,
wherein said introduction pipe is connected to a section of said joint pipe, on a downstream side of the flow of said atmosphere circulated by said air flow generator with respect to said filter.

15. The substrate processing device according to claim 1, wherein said substrate processing mechanism discharges said processing fluid to said substrate to perform one of cleaning processing and rinsing processing of said substrate.

16. The substrate processing device according to claim 15, wherein said substrate processing mechanism discharges one of pure water and functional water as said processing fluid.
